(19) United States
(12) Patent Application Publication
(10) Pub. No.: US 2023/0180561 A1
(43) Pub. Date: Jun. 8, 2023

(54) DISPLAY SUBSTRATE AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Zhongliu YANG, Beijing (CN); Wenbo CHEN, Beijing (CN); Mengyue FAN, Beijing (CN); Bing ZHANG, Beijing (CN); Shuang ZHAO, Beijing (CN); Jing YANG, Beijing (CN); Chenyu CHEN, Beijing (CN)

(21) Appl. No.: 17/921,920

(22) PCT Filed: May 20, 2021
(86) PCT No.: PCT/CN2021/094964

§ 371 Date: Oct. 27, 2022

(30) Foreign Application Priority Data
Jun. 10, 2020 (CN) 202010525723.9

(51) Int. Cl. H10K 59/131; H10K 59/121

(52) U.S. Cl. CPC H10K 59/1315; H10K 59/1213; H10K 59/1216

(57) ABSTRACT

The present disclosure provides a display substrate and a display device. The display substrate includes a substrate, a plurality of initialization signal lines, in the display area of the substrate, the plurality of initialization signal lines extend in a first direction; an interlayer insulating layer, on a side of the plurality of initialization signal lines facing away from the substrate; and a plurality of auxiliary signal lines, on a side of the interlayer insulating layer facing away from the substrate and in the display area, the plurality of auxiliary signal lines extend in a second direction, and the first direction is different from the second direction; the plurality of auxiliary signal lines and the plurality of initialization signal lines are electrically connected to each other through first vias, the first vias run through the interlayer insulating layer.

### CROSS-REFERENCE OF RELATED APPLICATIONS

The present disclosure is a National Stage of International Application No. PCT/CN2021/094964, filed May 20, 2021, which claims priority to Chinese Patent Application No. 202010525723.9, filed to the China National Intellectual Property Administration on Jun. 10, 2020 and entitled “DISPLAY PANEL AND DISPLAY DEVICE”, which is incorporated in its entirety herein by reference.

### FIELD OF INVENTION

The present disclosure relates to the technical field of display, and in particular to a display substrate and a display apparatus.

### BACKGROUND

At present, organic light-emitting diode (OLED) display substrates are one of the focuses in the research field of flat panel display. With the growth of the display technology, OLED display substrates have gradually developed towards large and medium sizes. However, as the OLED display substrates are enlarged, loading of signal lines for transmitting signals in the OLED display substrates is increased, which causes a delay in signal transmission and further affects display uniformity.

### BRIEF SUMMARY

An embodiment of the present disclosure provides a display substrate. The display substrate includes:

a substrate, having a display area and a peripheral area surrounding the display area;

a plurality of initialization signal lines, in the display area of the substrate, where the plurality of initialization signal lines extend in a first direction;

an interlayer insulating layer, on a side of the plurality of initialization signal lines facing away from the substrate; and

a plurality of auxiliary signal lines, on a side of the interlayer insulating layer facing away from the substrate and in the display area, where the plurality of auxiliary signal lines extend in a second direction, and the first direction is different from the second direction;

the plurality of auxiliary signal lines and the plurality of initialization signal lines are electrically connected to each other through first vias, the first vias run through the interlayer insulating layer, and orthographic projections of the first vias on the substrate are located at intersections of orthographic projections of the plurality of initialization signal lines on the substrate and orthographic projections of the plurality of auxiliary signal lines on the substrate.

In some embodiments, the display substrate further includes: a first auxiliary bus and a second auxiliary bus, in the peripheral area and extending in the first direction;

the first auxiliary bus and the second auxiliary bus are located at two ends of each auxiliary signal line respectively, and

the first auxiliary bus and the second auxiliary bus are electrically connected with the plurality of auxiliary signal lines respectively.

In some embodiments, the display substrate further includes: a third auxiliary bus and a fourth auxiliary bus, in the peripheral area and extending in the second direction;

the third auxiliary bus and the fourth auxiliary bus are located at two ends of each of the plurality of initialization signal lines respectively, and

the third auxiliary bus and the fourth auxiliary bus are electrically connected with the plurality of initialization signal lines respectively.

In some embodiments, the third auxiliary bus and the fourth auxiliary bus are in a same layer as the plurality of initialization signal lines.

In some embodiments, the display area further includes a plurality of sub-pixels; at least one of the plurality of sub-pixels includes a driving thin film transistor, a connecting electrode and a storage capacitor.

The driving thin film transistor includes a driving active layer, on the substrate; a driving gate, on a side of the driving active layer facing away from the substrate; a gate insulating layer, on a side of the driving gate facing away from the substrate; an interlayer dielectric layer, on a side of the gate insulating layer facing away from the substrate; and a driving source and a driving drain, on a side of the interlayer dielectric layer facing away from the substrate.

The connecting electrode is on a side of the driving source and the driving drain facing away from the substrate.

The storage capacitor includes a first capacitive electrode and a second capacitive electrode, the first capacitive electrode is in a same layer as the driving gate, and the second capacitive electrode is arranged between the gate insulating layer and the interlayer dielectric layer.

The plurality of initialization signal lines are in a same layer as the driving source and the driving drain.

The plurality of auxiliary signal lines are in a same layer as the connecting electrode.

At least one of the first auxiliary bus and the second auxiliary bus is in a same layer as the driving gate.

In some embodiments, the display substrate further includes: a plurality of power signal lines in the display area; the plurality of power signal lines extend in the second direction; and the power signal lines and the auxiliary signal lines are in a same layer, and the power signal lines and the auxiliary signal lines are arranged at intervals.

In some embodiments, the display substrate further includes: a first power bus and a second power bus, in the peripheral area and extending in the first direction; the first power bus and the second power bus are located at two ends of each power signal line respectively; and the first power bus and the second power bus are electrically connected with the plurality of power signal lines respectively.

In some embodiments, at least one of the first power bus and the second power bus is in a same layer as the plurality of power signal lines.

In some embodiments, the display substrate further includes: a plurality of power compensation lines in the display area and extending in the first direction;

the plurality of power compensation lines are in a same layer as the second capacitive electrode;

the plurality of power signal lines and the plurality of power compensation lines are electrically connected to each other through second vias, the second vias run through the interlayer insulating layer and the interlayer dielectric layer, and orthographic projections of the second vias on the substrate are located at intersections of orthographic projections of the plurality of power signal lines on the substrate and orthographic projections of the plurality of power compensation lines on the substrate.

In some embodiments, at least one of the plurality of sub-pixels further includes: a light-emitting diode, on a side of the connecting electrode facing away from the substrate; and the driving drain, the connecting electrode and the light-emitting diode are electrically connected with each other in sequence.

In some embodiments, an embodiment of the present disclosure further provides a display apparatus. The display apparatus includes the above display substrate.

### BRIEF DESCRIPTION OF THE DRAWINGS

FIG. 1 is a schematic structural diagram of some display substrates according to embodiments of the present disclosure.

FIG. 2 is a schematic structural diagram of sections of the display substrates shown in FIG. 1 in direction AA′.

FIG. 3 is a schematic structural diagram of sections of sub-pixels of a display substrate according to an embodiment of the present disclosure.

FIG. 4 is a schematic structural diagram of some other display substrates according to embodiments of the present disclosure.

### DETAILED DESCRIPTION OF THE EMBODIMENTS

In order to make objectives, technical solutions and advantages of the present disclosure clearer, specific implementations of a display substrate and a display apparatus provided in embodiments of the present disclosure will be described in detail below in combination with the accompanying drawings. It should be understood that the preferred embodiments described below are only used to state and explain the present disclosure, and are not used to limit the present disclosure. Moreover, embodiments in the present disclosure and features in the embodiments can be combined mutually if there is no conflict.

A thickness, a size and a shape of a film on each layer in the accompanying drawings do not reflect a real ratio of the display substrate, and are only intended to illustrate the contents of the present disclosure.

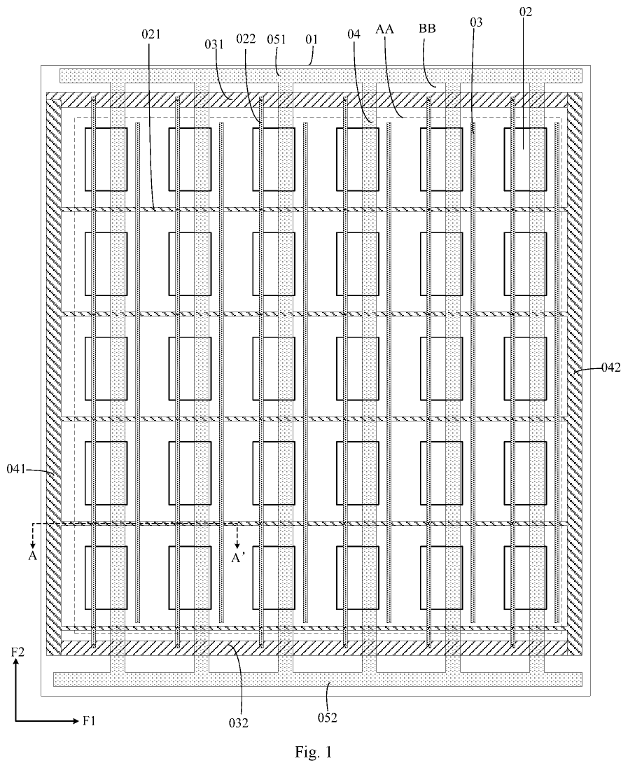

The display substrate provided in an embodiment of the present disclosure, as shown in FIG. 1, includes: a substrate 01 provided with a display area AA and a peripheral area BB surrounding the display area AA. A pixel array is arranged in the display area, and a circuit pattern is arranged in the peripheral area BB. The pixel array includes a plurality of sub-pixels and signal lines for driving the sub-pixels, and the signal lines include, for example, gate lines, data lines, power lines, etc. Generally, one gate line is arranged corresponding to each row of sub-pixels, and one data line or two data lines are arranged corresponding to each column of sub-pixels. A circuit pattern for providing corresponding signals for the gate lines and the data lines, for example, a gate-driver-on-array (GOA) circuit for providing signals for the gate lines, is arranged in the peripheral area BB.

In some embodiments, the display area may include a plurality of pixel units; and each pixel unit includes a plurality of sub-pixels. Illustratively, the pixel units may include red sub-pixels, green sub-pixels and blue sub-pixels, such that color display may be implemented by mixing red, green and blue; or the pixel units may include red sub-pixels, green sub-pixels, blue sub-pixels and white sub-pixels, such that color display may be implemented by mixing red, green, blue and white. Certainly, in practical applications, a color of light emitted by the sub-pixels of the pixel units may be designed and determined according to actual application environments, which is not limited herein.

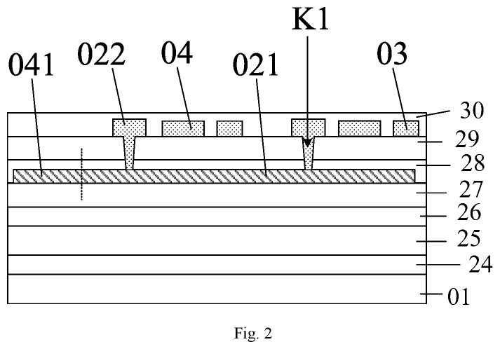

In some embodiments, as shown in FIGS. 1 and 2, at least one sub-pixel 02 (for example, each sub-pixel 02) of the plurality of sub-pixels 02 may include a pixel driving circuit and a light-emitting diode. The pixel driving circuit is provided with a transistor and a capacitor, an electric signal is generated through interaction of the transistor and the capacitor, and the generated electric signal is input into a first electrode of the light-emitting diode. A corresponding voltage is applied to a second electrode of the light-emitting diode, so as to drive the light-emitting diode to emit light.

Illustratively, the light-emitting diode may include at least one of an organic light emitting diode (OLED) and quantum dot light emitting diodes (QLEDs).

Illustratively, a pixel circuit of 7T1C may be used as the pixel driving circuit, or a pixel circuit of 7T2C may be used as the pixel driving circuit, which is not limited herein. Illustratively, the pixel driving circuit may be provided with an initialization transistor for resetting a gate of a driving transistor. In this way, by electrically connecting the initialization transistor to an initialization signal, when the initialization transistor is connected, the initialization signal transmitted on an initialization signal line 021 may be provided for the gate of the driving transistor, thereby resetting the gate of the driving transistor. However, as the display substrates are enlarged, loading of signal lines for transmitting initialization signals in the display substrates is increased, which causes a delay in initialization signal transmission, and further affects display uniformity.

On the basis of this, in some embodiments, as shown in FIGS. 1 and 2, the display substrate may include: a plurality of initialization signal lines 021 in the display area AA of the substrate 01, an interlayer insulating layer on a side of the plurality of initialization signal lines 021 facing away from the substrate 01, and a plurality of auxiliary signal lines 022 on a side of the interlayer insulating layer facing away from the substrate 01 and in the display area AA. The plurality of initialization signal lines 021 extend in a first direction F1, the plurality of auxiliary signal lines 022 extend in a second direction F2, and the first direction F1 is different from the second direction F2. The plurality of auxiliary signal lines 022 and the plurality of initialization signal lines 021 are electrically connected to each other through first vias K1, the first vias K1 run through the interlayer insulating layer, and orthographic projections of the first vias K1 on the substrate 01 are located at intersections of orthographic projections of the plurality of initialization signal lines 021 on the substrate 01 and orthographic projections of the plurality of auxiliary signal lines 022 on the substrate 01.

According to the display substrate provided in an embodiment of the present disclosure, the auxiliary signal lines 022 and the initialization signal lines 021 that intersect each other are arranged, the first vias K1 are provided at the intersections of the initialization signal lines 021 and the auxiliary signal lines 022, and the initialization signal lines 021 and the auxiliary signal lines 022 that correspond to each other are electrically connected to each other through the first vias K1, such that the initialization signal lines 021 and the auxiliary signal lines 022 that are electrically connected to each other are connected to each other in parallel, which is equivalent to the situation that the initialization signal lines 021 are connected to a resistor in parallel, so as to reduce equivalent resistance of the initialization signal lines 021. Since longer initialization signal lines 021 correspond to more first vias K1, the longer initialization signal lines 021 may be connected to more resistors in parallel, thereby reducing a delay of signal transmission. Further, the display substrate in the present disclosure may be advantageously applied to a large-size display apparatus to improve display uniformity.

Illustratively, the first direction F1 may be perpendicular to the second direction F2. For example, the first direction F1 is a row direction of the sub-pixels, and the second direction F2 is a column direction of the sub-pixels; or the first direction F1 is a column direction of the sub-pixels, and the second direction F2 is a row direction of the sub-pixels.

In some embodiments, as shown in FIGS. 1 and 2, the display substrate may further include: a first auxiliary bus 031 and a second auxiliary bus 032 in the peripheral area BB and extending in the first direction F1. The first auxiliary bus 031 and the second auxiliary bus 032 are located at two ends of each auxiliary signal line 022 respectively, and the first auxiliary bus 031 and the second auxiliary bus 032 are electrically connected with the plurality of auxiliary signal lines 022 respectively. In this way, ends of the plurality of auxiliary signal lines 022 are electrically connected to each other by the first auxiliary bus 031, and the other ends of the plurality of auxiliary signal lines 022 are electrically connected to each other by the second auxiliary bus 032.

In some embodiments, as shown in FIGS. 1 and 2, the display substrate may further include: a third auxiliary bus 041 and a fourth auxiliary bus 042 in the peripheral area BB and extending in the second direction F2. The third auxiliary bus 041 and the fourth auxiliary bus 042 are located at two ends of each of the plurality of initialization signal lines 021 respectively, and the third auxiliary bus 041 and the fourth auxiliary bus 042 are electrically connected with the plurality of initialization signal lines 021 respectively. Illustratively, the third auxiliary bus 041 and the fourth auxiliary bus 042 may be located on the same layer as the plurality of initialization signal lines 021. Thus, the third auxiliary bus 041, the fourth auxiliary bus 042 and the plurality of initialization signal lines 021 may be simultaneously made through a one-time patterning process.

In some embodiments, as shown in FIGS. 1 and 2, the display substrate may further include a plurality of data lines 03 and a plurality of gate lines (not shown in figures). The plurality of data lines 03 extend in the second direction F2, and the plurality of gate lines extend in the first direction F1. Illustratively, one row of sub-pixels are electrically connected to one gate line, and one column of sub-pixels are electrically connected to one data line 03 or two data lines 03, which is not limited herein.

In some embodiments, as shown in FIG. 1, the display substrate may further include: a plurality of power signal lines 04 in the display area. The plurality of power signal lines 04 extend in the second direction F2, and the power signal lines 04 and the auxiliary signal lines 022 are arranged in a same layer at intervals. In this way, a power signal VDD may be input to the pixel driving circuit by the power signal lines 04.

In some embodiments, as shown in FIG. 1, the display substrate may further include: a first power bus 051 and a second power bus 052 in the peripheral area BB and extending in the first direction F1. The first power bus 051 and the second power bus 052 are located at two ends of each power signal line 04 respectively, and the first power bus 051 and the second power bus 052 are electrically connected with the plurality of power signal lines 04 respectively. Thus, an influence of an IR drop of the power signal lines 04 on display uniformity may be further reduced.

In some embodiments, at least one of the first power bus 051 and the second power bus 052 is in a same layer as the power signal lines 04. For example, the first power bus 051 and the second power bus 052 are both in a same layer as the power signal lines 04. Thus, the first power bus 051 and the second power bus 052 may be simultaneously made through a one-time patterning process.

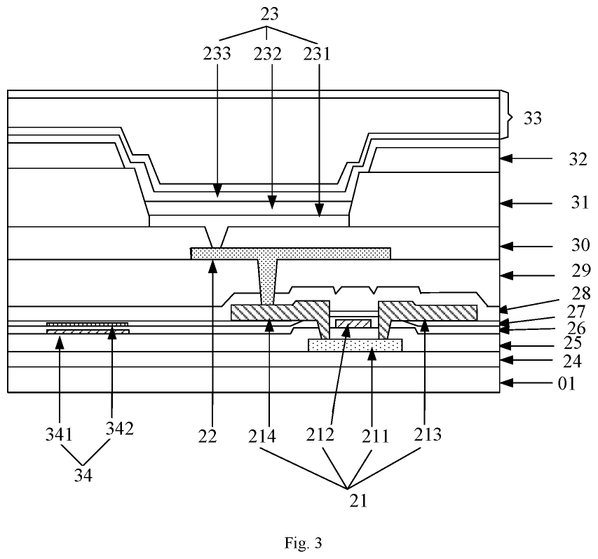

In some embodiments, as shown in FIG. 3, the pixel driving circuit may include a driving thin film transistor 21 and a connecting electrode 22 (the driving thin film transistor 21 and the connecting electrode 22 are only taken as an example for description). The driving thin film transistor 21 includes a driving active layer 211 on the substrate 01, a driving gate 212 on a side of the driving active layer 211 facing away from the substrate 01, and a driving source 213 and a driving drain 214 on a side of the driving gate 212 facing away from the substrate 01. The above connecting electrode 22 is on a side of the driving source 213 and the driving drain 214 facing away from the substrate 01. The light-emitting diode 23 (including a first electrode 231, a light-emitting layer 232 and a second electrode 233, which are arranged in a direction away from the substrate 01 in sequence) is located on a side of the connecting electrode 22 that is away from the substrate 01, and the driving drain 214, the connecting electrode 22 and the light-emitting diode 23 are electrically connected to each other in sequence. When a voltage is applied between the first electrode 231 and the second electrode 233, the light-emitting layer 232 may emit light. For example, the first electrode 231 of the light-emitting diode 23 is electrically connected to the driving drain 214 by the connecting electrode 22 such that the driving thin film transistor may control a light-emitting state of the light-emitting diode 23.

Illustratively, the driving gate 212 and the driving drain 214 may be made of a conductive material. For example, the conductive layer may be made of a metal material such as aluminum, molybdenum and titanium, or an alloy material, and may be a metal oxide such as indium tin oxide (ITO). An embodiment of the present disclosure does not limit a material of each functional layer.

In some embodiments, as shown in FIG. 3, each sub-pixel 02 may further include: a buffer layer 24, a first gate insulating layer 25, a second gate insulating layer 26, an interlayer dielectric layer 27, a passivation layer 28, a first planarization layer 29, a second planarization layer 30, a pixel defining layer 31, a supporting layer 32 and a sealing layer 33, which are arranged in a direction away from the substrate 01 in sequence. The above driving active layer 211 is arranged between the buffer layer 24 and the first gate insulating layer 25, the driving gate 212 is arranged between the first gate insulating layer 25 and the second gate insulating layer 26, the driving source 213 and the driving drain 214 are arranged between the interlayer dielectric layer 27 and the passivation layer 28, and the connecting electrode 22 is arranged between the first planarization layer 29 and the second planarization layer 30. The pixel defining layer 31 is configured to define a pixel area on the substrate 01, and the above light-emitting diode 23 is located in the pixel area.

For example, the interlayer insulating layer may include the passivation layer 28 and the first planarization layer 29.

For example, the pixel defining layer 31 includes a plurality of openings corresponding to the plurality of sub-pixels 02 respectively, and the light-emitting diodes 23 are formed in the plurality of openings respectively. For example, the sealing layer 33 may include a plurality of sealing sub-layers, such as the three sealing sub-layers shown in the figure. For example, the three sealing sub-layers include a first inorganic sealing sub-layer, an organic sealing sub-layer, and a second inorganic sealing sub-layer that are stacked, so as to enhance a sealing effect of the sealing layer 33.

For example, the gate insulating layer (including the first gate insulating layer 25 and the second gate insulating layer 26), the interlayer dielectric layer 27, the buffer layer 24, the planarization layer 28, the pixel defining layer 31, the supporting layer 32 and the sealing layer 33 are all made of insulating materials. According to requirements, organic insulating materials such as polyimide and resin materials may be selected, and inorganic insulating materials such as silicon oxide, silicon nitride and silicon oxynitride may be selected. An embodiment of the present disclosure does not limit the material of each functional layer.

It should be noted that the buffer layer 24, the first gate insulating layer 25, the second gate insulating layer 26, the interlayer dielectric layer 27, the passivation layer 28, the first planarization layer 29 and the second planarization layer 30 in the display area AA may all extend to the peripheral area BB, and the relative position relations of these film layers in the peripheral area BB is the same as that in the display area AA, which will not be repeated in embodiments of the present disclosure.

In addition, as shown in FIG. 3, the pixel driving circuit may further include: a storage capacitor 34. The storage capacitor 34 includes a first capacitive electrode 341 and a second capacitive electrode 342. The first capacitive electrode 341 is in a same layer as the driving gate 212, and the second capacitive electrode 342 is arranged between the second gate insulating layer 26 and the interlayer dielectric layer 27.

Illustratively, part of the structure of the display area AA may be in a same layer as part of the structure of the peripheral area BB of the display substrate, and these structures will be explained below. It should be noted that, in an embodiment of the present disclosure, the plurality of structures in a same layer means that the plurality of structures may be formed from the same material layer through a patterning process in a making process, thereby simplifying a process of making a display substrate.

Illustratively, the plurality of initialization signal lines 021 are in a same layer as the driving source and the driving drain. Thus, when the driving source and the driving drain in the display area AA are made, the initialization signal lines 021 may be simultaneously made, which simplifies a process of making a display substrate. Certainly, the initialization signal lines 021 may not be in a same layer as the driving source and the driving drain, which is not limited in an embodiment of the present disclosure.

Illustratively, the plurality of auxiliary signal lines 022 may be in a same layer as the connecting electrode. Thus, when the connecting electrode in the display area AA is made, the auxiliary signal lines 022 may be simultaneously made, which simplifies a process of making a display substrate. Certainly, the auxiliary signal lines 022 may not be in a same layer as the connecting electrode, which is not limited in an embodiment of the present disclosure.

Illustratively, at least one of the first auxiliary bus 031 and the second auxiliary bus 032 is in a same layer as the driving gate. For example, the first auxiliary bus 031 and the second auxiliary bus 032 are both in a same layer as the driving gate. Thus, when the driving gate in the display area AA is made, the first auxiliary bus 031 and the second auxiliary bus 032 in the peripheral area BB may be simultaneously made, which simplifies a process of making a display substrate. Certainly, the first auxiliary bus 031 and the second auxiliary bus 032 may not be in a same layer as the driving gate, which is not limited in an embodiment of the present disclosure.

Illustratively, the power signal lines 04 may be in a same layer as the connecting electrode. Thus, when the connecting electrode in the display area AA is made, the power signal lines 04 may be simultaneously made, which simplifies a process of making a display substrate. Certainly, the power signal lines 04 may not be in a same layer as the connecting electrode, which is not limited in an embodiment of the present disclosure.

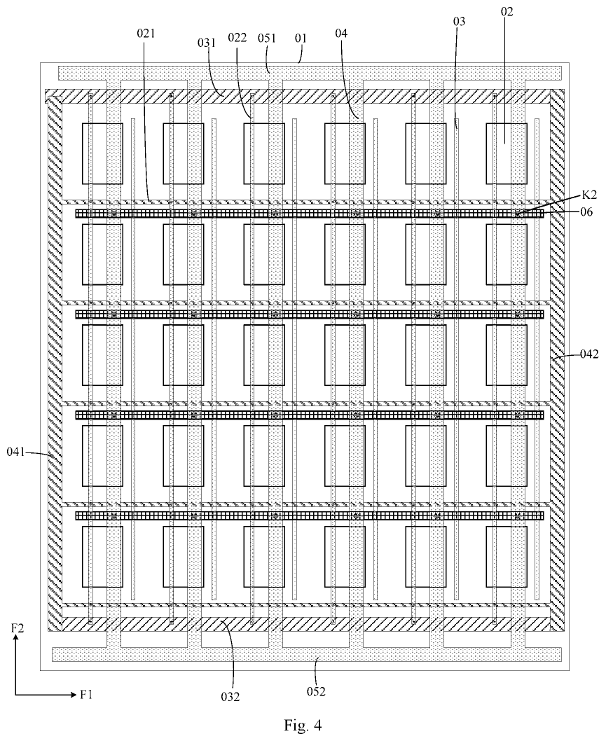

In some embodiments, as shown in FIG. 4, the display substrate may further include: a plurality of power compensation lines 06 in the display area and extending in the first direction F1. The plurality of power compensation lines 06 are in a same layer as the second capacitive electrode, the plurality of power signal lines 04 and the plurality of power compensation lines 06 are electrically connected with each other through second vias K2, the second vias K2 run through the interlayer insulating layer and the interlayer dielectric layer, and orthographic projections of the second vias K2 on the substrate 01 are located at intersections of orthographic projections of the plurality of power signal lines 04 on the substrate 01 and orthographic projections of the plurality of power compensation lines 06 on the substrate 01. In this way, the power compensation lines 06 and the power signal lines 04 that intersect each other are arranged, the second vias K2 are provided at the intersections of the power signal lines 04 and the power compensation lines 06, and the power signal lines 04 and the power compensation lines 06 that correspond to each other are electrically connected to each other through the second vias K2, such that the power signal lines 04 and the power compensation lines 06 that are electrically connected to each other are connected to each other in parallel, which is equivalent to the situation that the power signal lines 04 are connected to a resistor in parallel, so as to reduce equivalent resistance of the power signal lines 04. Since longer power signal lines 04 correspond to more second vias K2, the longer power signal line 04 may be connected to more resistors in parallel, thereby reducing a delay of signal transmission. Further, the display substrate in the present disclosure may be advantageously applied to a large-size display apparatus to improve display uniformity.

On the basis of the same inventive concept, an embodiment of the present disclosure further provides a display apparatus. The display apparatus includes the above display substrate provided in an embodiment of the present disclosure. The problem solving principle of the display apparatus is similar to that of the above display substrate such that the implementation of the display apparatus can be obtained with reference to the implementation of the above display substrate, which will not be repeated herein.

In some embodiments, the display apparatus can be a mobile phone, a tablet computer, a television, a display, a notebook computer, a digital photo frame, a navigator and other products or components having a display function. Other essential components of the display apparatus will be understood by those of ordinary skill in the art, are not repeated herein, and should not be taken as a limitation to the present disclosure.

According to the display substrate and the display apparatus provided in embodiments of the present disclosure, the auxiliary signal lines and the initialization signal lines that intersect each other are arranged, the first vias are provided at the intersections of the initialization signal lines and the auxiliary signal lines, and the initialization signal lines and the auxiliary signal lines that correspond to each other are electrically connected to each other through the first vias, such that the initialization signal lines and the auxiliary signal lines that are electrically connected to each other are connected to each other in parallel, which is equivalent to the situation that the initialization signal lines are connected to a resistor in parallel, so as to reduce equivalent resistance of the initialization signal lines. Since longer initialization signal lines correspond to more first vias, the longer initialization signal lines may be connected to more resistors in parallel, thereby reducing a delay of signal transmission. Further, the display substrate in the present disclosure may be advantageously applied to a large-size display apparatus to improve display uniformity.

Obviously, those skilled in the art can make various amendments and variations to the present disclosure without departing from the spirit and scope of the present disclosure. In this way, if these amendments and variations of the present disclosure fall within the scope of the claims of the present disclosure and equivalent technologies thereof, the present disclosure is further intended to include these amendments and variations.

1. A display substrate, comprising:
a substrate, having a display area and a peripheral area surrounding the display area;
a plurality of initialization signal lines, in the display area of the substrate, wherein the plurality of initialization signal lines extend in a first direction;
an interlayer insulating layer, on a side of the plurality of initialization signal lines facing away from the substrate; and
a plurality of auxiliary signal lines, on a side of the interlayer insulating layer facing away from the substrate and in the display area, wherein the plurality of auxiliary signal lines extend in a second direction, and the first direction is different from the second direction;
wherein the plurality of auxiliary signal lines and the plurality of initialization signal lines are electrically connected to each other through first vias, the first vias run through the interlayer insulating layer, and orthographic projections of the first vias on the substrate are located at intersections of orthographic projections of the plurality of initialization signal lines on the substrate and orthographic projections of the plurality of auxiliary signal lines on the substrate.

2. The display substrate according to claim 1, further comprising: a first auxiliary bus and a second auxiliary bus, in the peripheral area and extending in the first direction; wherein
the first auxiliary bus and the second auxiliary bus are located at two ends of each auxiliary signal line respectively, and
the first auxiliary bus and the second auxiliary bus are electrically connected with the plurality of auxiliary signal lines respectively.

3. The display substrate according to claim 2, further comprising: a third auxiliary bus and a fourth auxiliary bus, in the peripheral area and extending in the second direction; wherein
the third auxiliary bus and the fourth auxiliary bus are located at two ends of each of the plurality of initialization signal lines respectively, and
the third auxiliary bus and the fourth auxiliary bus are electrically connected with the plurality of initialization signal lines respectively.

4. The display substrate according to claim 3, wherein the third auxiliary bus and the fourth auxiliary bus are in a same layer as the plurality of initialization signal lines.

5. The display substrate according to claim 2, wherein the display area further comprises a plurality of sub-pixels; at least one of the plurality of sub-pixels comprises a driving thin film transistor, a connecting electrode and a storage capacitor;
the driving thin film transistor comprises:
a driving active layer, on the substrate;
a driving gate, on a side of the driving active layer facing away from the substrate;
a gate insulating layer, on a side of the driving gate facing away from the substrate;
an interlayer dielectric layer, on a side of the gate insulating layer facing away from the substrate; and
a driving source and a driving drain, on a side of the interlayer dielectric layer facing away from the substrate;
the connecting electrode is on a side of the driving source and the driving drain facing away from the substrate;
the storage capacitor comprises a first capacitive electrode and a second capacitive electrode, the first capacitive electrode is in a same layer as the driving gate, and the second capacitive electrode is arranged between the gate insulating layer and the interlayer dielectric layer;
the plurality of initialization signal lines are in a same layer as the driving source and the driving drain;
the plurality of auxiliary signal lines are in a same layer as the connecting electrode; and
at least one of the first auxiliary bus and the second auxiliary bus is in a same layer as the driving gate.

6. The display substrate according to claim 5, further comprising: a plurality of power signal lines in the display area; wherein:
the plurality of power signal lines extend in the second direction; and
the power signal lines and the auxiliary signal lines are in a same layer, and the power signal lines and the auxiliary signal lines are arranged at intervals.

7. The display substrate according to claim 6, further comprising: a first power bus and a second power bus, in the peripheral area and extending in the first direction; wherein:
the first power bus and the second power bus are located at two ends of each power signal line respectively; and
the first power bus and the second power bus are electrically connected with the plurality of power signal lines respectively.

8. The display substrate according to claim 7, wherein at least one of the first power bus and the second power bus is in a same layer as the plurality of power signal lines.

9. The display substrate according to claim 6, further comprising: a plurality of power compensation lines in the display area and extending in the first direction; wherein:
the plurality of power compensation lines are in a same layer as the second capacitive electrode;
the plurality of power signal lines and the plurality of power compensation lines are electrically connected to each other through second vias, the second vias run through the interlayer insulating layer and the interlayer dielectric layer, and orthographic projections of the second vias on the substrate are located at intersections of orthographic projections of the plurality of power signal lines on the substrate and orthographic projections of the plurality of power compensation lines on the substrate.

10. The display substrate according to claim 5, wherein at least one of the plurality of sub-pixels further comprises:
a light-emitting diode, on a side of the connecting electrode facing away from the substrate; and
wherein the driving drain, the connecting electrode and the light-emitting diode are electrically connected with each other in sequence.

11. A display apparatus, comprising the display substrate of claim 1.

12. The display apparatus according to claim 11, wherein the display substrate further comprises: a first auxiliary bus and a second auxiliary bus, in the peripheral area and extending in the first direction; wherein
the first auxiliary bus and the second auxiliary bus are located at two ends of each auxiliary signal line respectively, and
the first auxiliary bus and the second auxiliary bus are electrically connected with the plurality of auxiliary signal lines respectively.

13. The display apparatus according to claim 12, wherein the display substrate further comprises: a third auxiliary bus and a fourth auxiliary bus, in the peripheral area and extending in the second direction; wherein
the third auxiliary bus and the fourth auxiliary bus are located at two ends of each of the plurality of initialization signal lines respectively, and
the third auxiliary bus and the fourth auxiliary bus are electrically connected with the plurality of initialization signal lines respectively.

14. The display apparatus according to claim 13, wherein the third auxiliary bus and the fourth auxiliary bus are in a same layer as the plurality of initialization signal lines.

15. The display apparatus according to claim 12, wherein the display area further comprises a plurality of sub-pixels; at least one of the plurality of sub-pixels comprises a driving thin film transistor, a connecting electrode and a storage capacitor;
the driving thin film transistor comprises:
a driving active layer, on the substrate;
a driving gate, on a side of the driving active layer facing away from the substrate;
a gate insulating layer, on a side of the driving gate facing away from the substrate;
an interlayer dielectric layer, on a side of the gate insulating layer facing away from the substrate; and
a driving source and a driving drain, on a side of the interlayer dielectric layer facing away from the substrate;
the connecting electrode is on a side of the driving source and the driving drain facing away from the substrate;
the storage capacitor comprises a first capacitive electrode and a second capacitive electrode, the first capacitive electrode is in a same layer as the driving gate, and the second capacitive electrode is arranged between the gate insulating layer and the interlayer dielectric layer;
the plurality of initialization signal lines are in a same layer as the driving source and the driving drain;
the plurality of auxiliary signal lines are in a same layer as the connecting electrode; and
at least one of the first auxiliary bus and the second auxiliary bus is in a same layer as the driving gate.

16. The display apparatus according to claim 5, wherein the display substrate further comprises: a plurality of power signal lines in the display area; wherein:
the plurality of power signal lines extend in the second direction; and
the power signal lines and the auxiliary signal lines are in a same layer, and the power signal lines and the auxiliary signal lines are arranged at intervals.

17. The display apparatus according to claim 16, wherein the display substrate further comprises: a first power bus and a second power bus, in the peripheral area and extending in the first direction; wherein:
the first power bus and the second power bus are located at two ends of each power signal line respectively; and
the first power bus and the second power bus are electrically connected with the plurality of power signal lines respectively.

18. The display apparatus according to claim 17, wherein at least one of the first power bus and the second power bus is in a same layer as the plurality of power signal lines.

19. The display apparatus according to claim 16, wherein the display substrate further comprises: a plurality of power compensation lines in the display area and extending in the first direction; wherein:
the plurality of power compensation lines are in a same layer as the second capacitive electrode;
the plurality of power signal lines and the plurality of power compensation lines are electrically connected to each other through second vias, the second vias run through the interlayer insulating layer and the interlayer dielectric layer, and orthographic projections of the second vias on the substrate are located at intersections of orthographic projections of the plurality of power signal lines on the substrate and orthographic projections of the plurality of power compensation lines on the substrate.

20. The display apparatus according to claim 15, wherein at least one of the plurality of sub-pixels further comprises:
a light-emitting diode, on a side of the connecting electrode facing away from the substrate; and
wherein the driving drain, the connecting electrode and the light-emitting diode are electrically connected with each other in sequence.
